(19) United States
(12) Patent Application Publication
(10) Pub. No.: US 2008/0199281 A1
(43) Pub. Date: Aug. 21, 2008

(54) Vacuum System For Wafer Handling

(75) Inventors: Vincenzo Ogliari, Capergnanica (IT); Franco Preti, Milano (IT)

Correspondence Address: KATTEN MUCHIN ROSENMAN LLP, 575 MADISON AVENUE, NEW YORK, NY, 10022-2585, US

(73) Assignee: LPE S.P.A., Bollate (MI) (IT)

(21) Appl. No.: 11/912,753

(22) PCT Filed: May 26, 2005
(86) PCT No.: PCT/IT05/00301

§ 371 Date: Oct. 26, 2007

(51) Int. Cl. H01L 21/68

(52) U.S. Cl. 414/217; 414/805

(57) ABSTRACT

The present invention relates to a system for handling wafers (W) within a treatment apparatus (1) comprising a suction system (10) equipped with a suction inlet, a suction pipe (7) having a first end and a second end, said first end being connected to the suction inlet of the suction system (10), a tool (6) suitable for handling wafers (W) and for holding them by suction, and connected to the second end of the suction pipe (7), and a device for regulating the pressure in the suction pipe; the regulating device comprises a valve (8) connected to the suction pipe (7) and capable of opening when the pressure in the suction pipe (7) falls below a predetermined value.

The present invention relates principally to a system for handling wafers within a treatment apparatus according to the preamble of claim 1.

An apparatus for treating wafers where the present invention advantageously finds an application is described in U.S. Pat. No. 6,648,974, which is incorporated herein by reference.

In that patent there in also described a tool suitable for handling wafers and for holding them by suction; the tool is connected to a suction pipe which is in turn connected to a suction system.

The tool is configured in such a manner that the suction effect on the wafer is low; in this way, there is no risk of deforming the wafer; however, situations may arise in which it is difficult for the tool to hold or grip the wafer.

US Patent Application 2004/0191029 describes a tool suitable for handling wafers and for holding same by suction and which is an improvement of the tool according to the patent mentioned above.

That patent application is incorporated herein by reference.

The improved tool is configured in such a manner that the suction effect on the wafer is high; in this way, there is no difficulty in gripping or holding the wafer; moreover, it has been found that in most cases the wafer is not deformed in a harmful manner; however, situations may arise in which the suction becomes harmful.

If a suction system is used in which the suction can be set, it is possible to adapt the suction to the various operating conditions of the wafer handling system. However, it is not possible to take into account unforeseeable factors such as, for example, the degree of alignment of the wafer with respect to the tool, the deformation of the wafer and/or of the tool and/or of the support for the wafer.

A common method of solving this problem is that of setting a suction much higher than the theoretical minimum required.

It is a general aim of the present invention to remedy the drawbacks of the prior art.

A more specific aim of the present invention is that of providing a system for handling wafers which is capable of gripping and holding the wafers properly but which avoids excessive suction effects in a simple manner.

These and other aims are achieved by means of the wafer handling system having the features recited in the claims appended hereto.

The idea underlying the present invention is that of using a simple valve which succeeds in regulating the pressure in a simple, reliable, effective and rapid manner; the presence of the valve does not however exclude a suction system of the type that can be set, for example computerised, by means of which sophisticated strategies can be carried out.

Moreover, according to another aspect, the present invention also relates to a method for regulating the pressure in a wafer handling system.

Finally, according to another aspect, the present invention also relates to an apparatus for treating wafers.

The present invention will become clearer from the following description to be considered together with the appended drawings, in which:

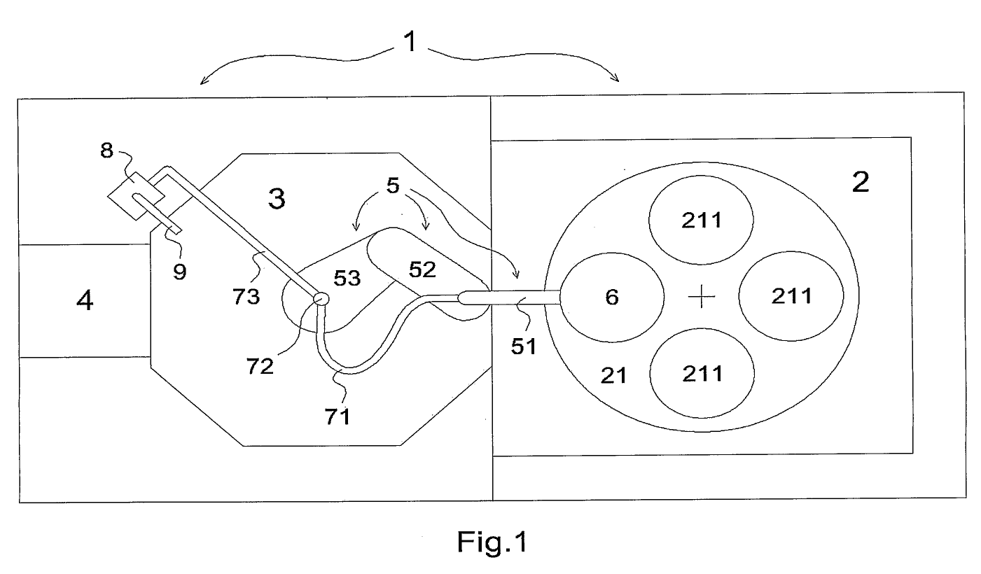

FIG. 1 shows diagrammatically an apparatus for treating wafers according to the present invention,

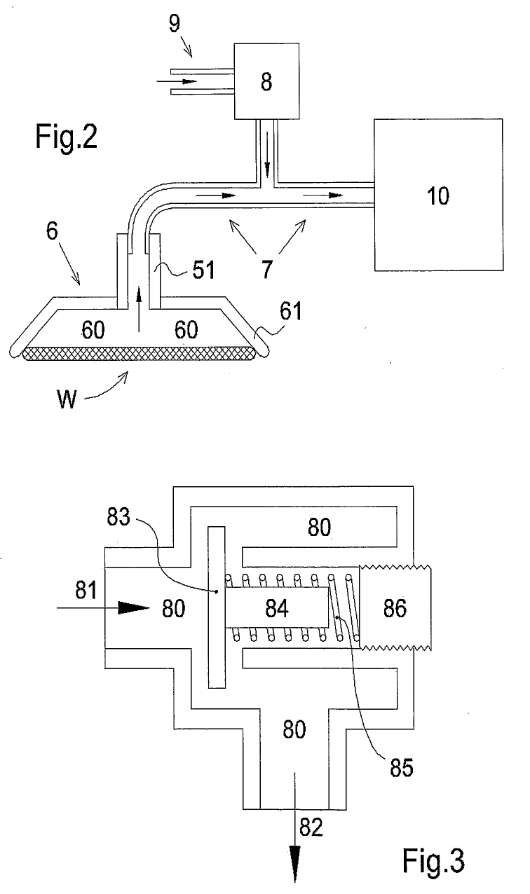

FIG. 2 shows diagrammatically a wafer handling system according to the present invention, and

FIG. 3 shows diagrammatically a device for regulating the pressure of the system in FIG. 2.

Both the description and the drawings are to be regarded solely as for purposes of example and therefore non-limiting.

FIG. 1 shows an exemplary embodiment of an apparatus for treating wafers according to the present invention; the apparatus is indicated as a whole by the reference 1 and is, in particular, a “pancake” type epitaxial reactor heated by induction.

The apparatus 1 comprises a reaction chamber 2, a transfer chamber 3, a flushing chamber 4, and a storage zone not shown in the drawing.

Placed in the transfer chamber 3 is the arm of a robot 5 which provides, before the treatment, for the wafers to be extracted one at a time from the flushing chamber 4 and to be inserted into the reaction chamber 2, and, after the treatment, for the wafers to be extracted one at a time from the reaction chamber 2 and to be inserted into the flushing chamber 4.

Placed in the reaction chamber 2 is a support 21 for the wafers to be treated. In the example of FIG. 1, the support 21 is capable of supporting four wafers. Alternatively, as is well known, the support may support a number of wafers varying from a minimum of one to a maximum of several dozen, in relation to the diameter of the support and to the diameter of the wafers. The wafers are received in hollows 211 provided on the upper surface of the support 21. The support 21 is rotatable, such that the robot 5 can position the various wafers in the various hollows 211 with a movement that is always the same.

In order to carry out the required movements, the robot 5 is equipped with an arm comprising members suitably articulated with one another; in the example of FIG. 1, the arm comprises three members 51, 52 and 53; to an end member 51 of the arm is fitted a tool 6 suitable for handling the wafers, one at a time, and for holding them by suction. In the example of FIG. 1, the member 51 is constituted by a rigid tube, which also functions as a suction passage. The tube 51 is connected on one side to a suction system 10 (not visible in FIG. 1 and which can be seen diagrammatically in FIG. 2) via a suction pipe 7 and, on the other side, to the tool 6 in such a manner as to place the suction tool 6 in communication with the suction system 10.

The suction pipe 7 is composed of a flexible tube 71 followed by a rigid tube 73 connected to the flexible tube via a rotatable joint 72.

In the apparatus 1, outside the transfer chamber 3, in the immediate vicinity thereof, is placed a device 8 for regulating the pressure in the suction pipe 7; the device 8 is connected to the suction pipe 7, in particular to the rigid tube 73, and to a tube 9 which opens into the transfer chamber 3.

Referring now to FIG. 2, the tool 6 is capable of handling a wafer W in an apparatus for treating wafers. The tool 6 is suitable for being fitted to the member 51 of the arm of the robot and is equipped with a suction passage connected to the suction pipe 7 which is connected to the suction system 10 of the apparatus 1.

The tool 6 comprises a body 61 configured and dimensioned for contacting the edge of a wafer W so as to form a suction chamber 60 between the body 61 and the wafer W. A tool of this type is very efficient for gripping a wafer since it is capable of exerting a high suction effect on the wafer owing to the suction chamber (substantially closed) which forms when the wafer is in good contact with the body of the tool.

Moreover, the body 61 is mounted on the tube 51 so that the suction chamber 60 communicates with the suction pipe 7.

The device 8 contained in the system of FIG. 2 is a valve and is shown in detail, but diagrammatically, in FIG. 3.

The valve 8 comprises a passage 80 equipped with an inlet 81 connected to the tube 9 and an outlet 82 connected to the tube 73; there is a movable member, constituted by a disc 83 joined to a rod 84, which can slide in an internal seat of the valve; a first end of a spring 85, within the seat, presses on the disc 83 of the movable member so as to keep the passage 80 closed; a second end of the spring 85 presses on a screw 86, screwed into the seat; the screw 86 is accessible from outside the valve so as to regulate the force which it exerts on the movable member.

When the difference between the pressure at the inlet 81 of the valve (that is to say, the pressure in the transfer chamber 3) and the pressure at the outlet 82 of the valve (that is to say, the pressure in the suction pipe 7, which is substantially uniform along the length of the pipe) exceeds a predetermined value, the spring 85 can no longer keep the passage 80 closed via the disc 83 and therefore a flow of gas takes place between the inlet 81 and the outlet 82; the predetermined value depends on the elastic constant of the spring 85 and on the position of the screw 86 and therefore on how far the screw 86 is screwed into the seat of the valve.

In FIG. 3, the movable member, in particular the disc 83, of the valve is shown in a state substantially of maximum opening; in fact the passage cross-section on the front of the disc 83 corresponds substantially to the passage cross-section on the side of the disc 83.

It should be noted that a valve such as that shown diagrammatically in FIG. 3 effects a substantially proportional type regulation. Alternatively, if an ON/OFF (or open/closed) type of regulation is used, there would be a risk of creating unwanted vibration in the apparatus 1, which could also have repercussions on the quality of the wafers treated.

In general, the handling system according to the present invention comprises:
a suction system equipped with a suction inlet,
a suction pipe having a first end and a second end, the first end being connected to the suction inlet of the suction system,
a tool suitable for handling wafers and for holding them by suction, and connected to the second end of the suction pipe, and
a device for regulating the pressure in the suction pipe;
   the regulating device comprises a valve connected to the suction pipe and capable of opening when the pressure in the suction pipe falls below a predetermined value.

This general definition of the present invention may be easily understood by referring by way of example to FIG. 2 in which, as already stated, 6 is a tool, 7 is a suction pipe, 8 is a valve and 10 is a suction system.

Owing to the valve, a rather simple device (even though for the type of application it is necessary to provide a device of good quality), it is possible to avoid the formation of an excessive under-pressure in the suction pipe and therefore excessive suction by the tool; moreover, the valve has a rather reduced response time; finally, the valve can advantageously effect a substantially proportional regulation.

For the purposes of the present invention, in general, the valve may comprise a passage, a spring and a movable member capable of closing the passage under the action of the spring; obviously, the passage opens when the pressure which acts on the movable member overrides the action of the spring.

This general definition of the valve may be easily understood by referring by way of example to FIG. 3. In particular, on a first side the passage is connected to the suction pipe, and on a second side the passage is connected to an internal chamber of the treatment apparatus, advantageously to the transfer chamber of the epitaxial reactor; in this way, only gases compatible with the treatment circulate in the suction system circuit.

It is advantageous to enable the valve to be calibrated and for the pressure value at which it opens to depend on such calibration; in this way, it is possible to compensate for constructional variations of the valve, and also of the components which constitute the suction circuit (body of the tool, parts of the suction pipe, etc.) and variations of the climatic conditions of operation of the apparatus (for example, the temperature).

A simple method for making calibration possible is that of providing a calibrating screw which acts on the spring; the valve is calibrated by rotation of the screw; this is the case in the example of FIG. 3.

The use of a pressure regulating valve does not in the least exclude the handling system from being provided with a suction system with a suction that can be set or regulated; in fact the settings (regulation with open ring) or the regulation (regulation with closed ring) will be used in the case of normal operation and the valve will intervene only in case of need, typically when anomalous situations occur. Moreover, a valve such as that defined in general above cuts out automatically and autonomously when there is no longer any need for it, typically when the anomalous situations have come to an end.

If a suction system with a suction that can be regulated is used, the handling system according to the present invention is equipped with two regulating means; the regulation effected by the valve is rapid, simple and reliable; the regulation effected by the suction system, typically by means of an electronic system, often computerised, is slower, more complex and dependent upon the correction functioning of the electronic system.

A suction system (that can be set) that is very advantageous for use in combination with the pressure regulating valve comprises an ejection device fed by a flow of inert gas; the flow of inert gas is controlled by a mass flow controller, known in English by the acronym MFC, of the type that can be programmed. There are currently on the market ejection devices of the single-stage type and of the multi-stage type; in these devices, the pressure difference is not constant but depends on the suction capacity.

The handling system according to the present invention is advantageously of the automatic type; to this end, it comprises a robot with articulated arm on which is mounted the tool for handling the wafers.

In general, the suction pipe of the handling system will be composed of several parts; in particular, a flexible tube may be basically provided, followed preferably by a rigid tube connected to the flexible tube via a rotatable joint. Such a configuration lends itself particularly well to being used in combination with the robot with articulated arm, as in the example of FIG. 1; in fact, the flexible tube allows the movement of the robot and the rotatable joint avoids mechanical stresses along the suction pipe, in particular at the junction between the rigid tube and the flexible tube.

The handling system with regulating valve lends itself especially well to being used with a tool of a particular type. The tool comprises a body configured and dimensioned for contacting the edge of a wafer so as to form a suction chamber between the body and the wafer, and means are provided for placing the suction chamber in communication with the suction pipe; this is the case with the tool shown diagrammatically in FIG. 2, in which the reference 60 indicates a suction chamber, 61 a body of a tool 6 and W a wafer.

As already stated, the present invention also has as its subject an apparatus for treating wafers, in particular an epitaxial reactor, which comprises a wafer handling system having the technical characteristics described above.

If the apparatus comprises a transfer chamber, it is of advantage to provide for the valve of the regulating device of the handling system to be connected to the transfer chamber.

Moreover, if the handling system is equipped with a robot having an arm it is of advantage to provide for at least the arm of the robot to be housed within the transfer chamber.

From the methodological point of view, the teaching of the present invention is fundamentally to connect a valve to the suction pipe and to open the valve when the pressure in the suction pipe falls below a predetermined value.

Advantageously, the opening of the valve is gradual, so as to provide a substantially proportional type of control.

Moreover, still from the methodological point of view, it is good to connect the suction pipe to a suction system with a suction that can be set or regulated.

Finally, still from the methodological point of view, it is good to use a tool comprising a body configured and dimensioned for contacting the edge of a wafer so as to form a suction chamber between the body and the wafer, and means for placing said suction chamber in communication with said suction pipe.

1.-17. (canceled)

18. A system for handling wafers within a treatment apparatus comprising:
a suction system equipped with a suction inlet, said suction system having a suction that can be set or regulated,
a suction pipe having a first end and a second end, said first end being connected to the suction inlet of the suction system,
a tool suitable for handling wafers and for holding them by suction, and connected to the second end of the suction pipe, and
a device for regulating the pressure in the suction pipe in addition to the possible regulating means of said suction system;
wherein said regulating device comprises a valve connected to the suction pipe and capable of opening when the pressure in the suction pipe falls below a predetermined value.

19. A system according to claim 18, wherein the valve comprises a passage, a spring and a movable member capable of closing said passage under the action of said spring.

20. A system according to claim 19, wherein said passage is connected on one side to said suction pipe.

21. A system according to claim 20, wherein said passage is connected on a second side to an internal chamber of said treatment apparatus.

22. A system according to claim 18, wherein said valve can be calibrated and said predetermined value depends on the calibration of said valve.

23. A system according to claim 22, comprising a calibrating screw which acts on said spring, wherein the calibration of said valve is effected by means of rotation of said screw.

24. A system according to claim 18, wherein said suction system comprises an ejection device fed by a flow of inert gas, said flow of inert gas being controlled by a programmable mass flow controller.

25. A system according to claim 18, comprising a robot having an articulated arm on which said tool (6) is mounted.

26. A system according to claim 18, wherein said suction pipe is constituted basically by a flexible tube preferably followed by a rigid tube connected to the flexible tube via a rotatable joint.

27. A system according to claim 18, wherein said tool comprises a body configured and dimensioned for contacting the edge of a wafer so as to form a suction chamber between the body and the wafer, and means are provided for placing said suction chamber in communication with said suction pipe.

28. An apparatus for treating wafers, comprising a wafer handling system according to claim 18.

29. An apparatus according to claim 28, comprising a transfer chamber, in which the valve of the device for regulating the handling system is connected to said transfer chamber.

30. An apparatus according to claim 28, comprising a transfer chamber, wherein at least the arm of the robot of the handling system is housed within said transfer chamber.

31. A method for regulating the pressure in a system for handling wafers, said system being of the type comprising a tool connected to a suction pipe, wherein a valve is connected to the suction pipe and the valve is opened when the pressure in the suction pipe falls below a predetermined value.

32. A method according to claim 31, wherein the suction pipe is connected to a suction system having a suction that can be set or regulated.

33. A method according to claim 31, wherein a tool is used which comprises a body configured and dimensioned for contacting the edge of a wafer so as to form a suction chamber between the body and the wafer, and means are used for placing said suction chamber in communication with said suction pipe.
